(19) United States
(12) Patent Application Publication
(10) Pub. No.: US 2020/0357847 A1
(43) Pub. Date: Nov. 12, 2020

(54) LED LIGHT SOURCE SUBSTRATE AND ILLUMINATION DEVICE

(71) Applicant: SHARP KABUSHIKI KAISHA, Sakai City (JP)

(72) Inventors: HISASHI WATANABE, Sakai City (JP); TAKESHI MASUDA, Sakai City (JP); HIROTOSHI YASUNAGA, Sakai City (JP); YOUZOU KYOUKANE, Sakai City (JP)

(21) Appl. No.: 16/861,786

(22) Filed: Apr. 29, 2020

(30) Foreign Application Priority Data
May 10, 2019 (JP) 2019-090007

(51) Int. Cl. H01L 27/15; F21K 9/68; H01L 33/56; H01L 33/60; H01L 33/62; H01L 33/46; H01L 33/10

(52) U.S. Cl. CPC H01L 27/156; F21K 9/68; H01L 33/56; H01L 33/10; H01L 33/62; H01L 33/46; H01L 33/60

(57) ABSTRACT

A light emitting diode (LED) light source substrate includes a substrate, a plurality of LEDs of a flip-chip type, a bonding sheet, a plurality of reflective layers, and a substrate reflective layer, formed on the substrate, configured to reflect a first light that passes between the plurality of reflective layers and is incident on the bonding sheet. A reflectivity of the substrate reflective layer configured to reflect the first light is substantially equal to a reflectivity of the plurality of reflective layers configured to reflect a second light incident on the plurality of reflective layers from a side opposite to the substrate.

### CROSS-REFERENCE TO RELATED APPLICATIONS

This application claims the benefit of priority to Japanese Patent Application Number 2019-090007 filed on May 10, 2019. The entire contents of the above-identified application are hereby incorporated by reference.

### BACKGROUND

### Technical Field

The disclosure relates to a light emitting diode (LED) light source substrate including an LED of a flip-chip type.

There are known various types of light sources of illumination devices (backlights) attached to display devices and the like, including light sources that use a light emitting diode (LED). In the related art, LEDs of a surface-mounted type have been used in illumination devices of a direct-lighting type in which the light source is disposed directly below the display panel. As a light source substrate with a mounted LED, there is known an LED light source substrate in which a plurality of LEDs are mounted on the same circuit substrate, and a mold resin is extended over the plurality of LEDs, covering the plurality of LEDs. A white ink based reflective layer is formed directly above the LEDs above this mold resin (JP 2007-53352 A, Mar. 1, 2007).

### SUMMARY

On the surface of the circuit substrate provided to the LED light source substrate is provided a white insulating layer having high reflectivity, commonly referred to as a resist, on a copper foil that forms the circuit. When a reflectivity, a tinge, and the like of this resist differ from a reflectivity, a tinge, and the like of the reflective layer formed on the mold resin directly above the LEDs and the circuit substrate is viewed from the reflective layer side, a reflectivity of light that passes between the plurality of reflective layers, is incident on the mold resin, and is reflected by the resist differs from a reflectivity of light incident on the reflective layers from a side opposite to the circuit substrate and reflected by the reflective layers. Therefore, a distribution of reflectivity and the like exists between the reflected light from the resist and the reflected light from the reflective layers.

A backlight including such an LED light source substrate has a structure in which a diffuser sheet, a prism sheet, and the like are layered above this LED light source substrate, and light emitted from the LEDs is refracted, reflected, scattered, and the like by the diffuser sheet, the prism sheet, and the like, thereby enhancing a uniformity of the light output from the backlight while returning the light to a surface of the circuit substrate for reuse.

Therefore, when there is a distribution of reflectivity between the reflected light from the resist of the circuit substrate and the reflected light from the reflective layers, the output light from the backlight picks up the distribution of the reflectivity, and there is a problem that unevenness occurs in the output light from the backlight.

An object of an aspect of the disclosure is to provide an LED light source substrate capable of suppressing an unevenness of output light from a backlight.

A light emitting diode (LED) light source substrate according to an aspect of the disclosure includes a substrate, a plurality of LEDs of a flip-chip type mounted on the substrate, a transparent layer formed on the substrate, embedding the plurality of LEDs, and having a refractive index greater than 1, a plurality of reflective layers formed on the transparent layer in correspondence with the plurality of LEDs, and a substrate reflective layer, formed on the substrate, configured to reflect a first light that passes between the plurality of reflective layers and is incident on the transparent layer. A reflectivity of the substrate reflective layer configured to reflect the first light is substantially equal to a reflectivity of the plurality of reflective layers configured to reflect a second light incident on the plurality of reflective layers from a side opposite to the substrate.

An illumination device according to an aspect of the disclosure includes the LED light source substrate according to an aspect of the disclosure.

According to an aspect of the disclosure, it is possible to provide an LED light source substrate capable of suppressing an unevenness of output light from a backlight.

### BRIEF DESCRIPTION OF DRAWINGS

The disclosure will be described with reference to the accompanying drawings, wherein like numbers reference like elements.

FIG. 1 is a cross-sectional view of a light emitting diode (LED) light source substrate according to a first embodiment.

FIG. 2A is a cross-sectional view illustrating a mounted state of a LED of a flip-chip type provided to the LED light source substrate, FIG. 2B is a cross-sectional view illustrating a mounted state of a LED of a face-up type, FIG. 2C is a cross-sectional view illustrating a configuration of the LED of the flip-chip type, and FIG. 2D is a cross-sectional view illustrating a configuration of the LED of the face-up type.

FIG. 3A is an enlarged cross-sectional view of an LED of the LED light source substrate, and FIG. 3B is an enlarged cross-sectional view of an LED of an LED light source substrate according to the comparative example.

FIG. 4A is a cross-sectional view according to a substrate, a bonding sheet, and a plurality of reflective layers of the LED light source substrate, and FIG. 4B is a top view thereof.

FIG. 5A is a cross-sectional view illustrating a method for forming the bonding sheet, and FIG. 5B is a cross-sectional view illustrating a state of the bonding sheet formed on the substrate.

FIG. 6A is a cross-sectional view for describing an effect of an adhesive layer provided to the bonding sheet, and FIG. 6B is a cross-sectional view illustrating an adhesive layer according to a comparative example.

FIG. 7A and FIG. 7B are cross-sectional views for describing an effect of a substrate reflective layer provided to the LED light source substrate.

FIG. 8A is a cross-sectional view of an LED light source substrate according to a second embodiment, and FIG. 8B is a plan view thereof.

FIG. 9A is a cross-sectional view describing an effect of the LED light source substrate according to the second embodiment, FIG. 9B is a cross-sectional view illustrating a base material of the bonding sheet provided to the LED light source substrate, and FIG. 9C is a cross-sectional view illustrating a base material of a bonding sheet according to a comparative example.

FIG. 10A is a cross-sectional view of an LED light source substrate according to a third embodiment, FIG. 10B is a cross-sectional view illustrating a relationship between a substrate reflective layer and the LED provided to the LED light source substrate, FIG. 10C is a cross-sectional view illustrating a relationship between a substrate reflective layer and the LED according to a comparative example, and FIG. 10D is a cross-sectional view illustrating a relationship between a substrate reflective layer and the LED according to a modified example.

FIG. 11A is a cross-sectional view of an LED light source substrate according to embodiment 4, FIG. 11B is a cross-sectional view illustrating a relationship between a substrate reflective layer and the LED provided to the LED light source substrate, and FIG. 11C is a cross-sectional view illustrating a relationship between a substrate reflective layer and the LED according to a comparative example.

### DESCRIPTION OF EMBODIMENTS

In the specification herein, “reflectivity” refers to the reflectivity measured by a spectrophotometer according to the measurement method defined in Japanese Industrial Standards (JIS) Z 8722. Applicable spectrophotometers include, for example, CM-5 manufactured by Konica Minolta (https://www.konicaminolta.jp/instruments/products/color/cm5/spe c.html).

### First Embodiment

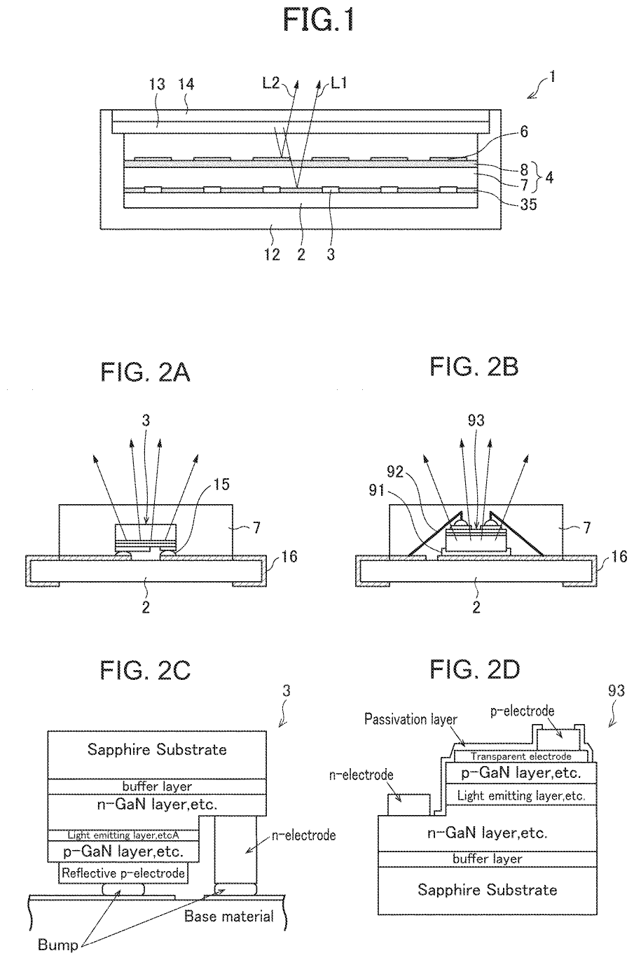

FIG. 1 is a cross-sectional view of a light emitting diode (LED) light source substrate 1 according to the first embodiment. The LED light source substrate 1 includes a substrate 2, a plurality of LEDs 3 of a flip-chip type that are mounted on the substrate 2, a bonding sheet 4 (transparent layer) that is light-transmitting formed on the substrate 2 and embedding the plurality of LEDs 3, and a plurality of reflective layers 6, formed in correspondence with the plurality of LEDs 3 on the bonding sheet 4, and configured to suppress light emitted respectively from the plurality of LEDs 3 in a direction orthogonal to the substrate 2.

Then, a substrate reflective layer 35 configured to reflect a first light L1 that passes between the plurality of reflective layers 6 and is incident on the bonding sheet 4 is formed on the substrate 2. A reflectivity of the substrate reflective layer 35 configured to reflect the first light L1 is substantially equal to a reflectivity of each of the plurality of reflective layers 6 configured to reflect a second light L2 incident on the plurality of reflective layers 6 from a side opposite to the substrate 2.

Further, even more preferably, a color level of the substrate reflective layer 35 configured to reflect the first light L1 is substantially equal to a color level of each of the plurality of reflective layers 6 configured to reflect the second light L2 incident on the plurality of reflective layers 6 from the side opposite to the substrate 2. Note that a range in which the reflectivities are substantially equal is, for example, within ±5% measured by a spectrophotometer, and a range in which the color levels are substantially equal is, for example, within x=±0.01 and within y=±0.01 based on xy chromaticity coordinates similarly measured by a spectrophotometer.

Preferably, the substrate reflective layer 35 is formed of a same material as that of the plurality of reflective layers 6. Preferably, a ratio of a thickness of the substrate reflective layer 35 to a thickness of each of the plurality of reflective layers 6 is greater than or equal to 1 and less than or equal to 1.5.

The bonding sheet 4 includes an adhesive layer 7 (resin layer, transparent layer) formed on the substrate 2, embedding the plurality of LEDs 3, and a base material 8 (transparent layer) formed on the adhesive layer 7.

Preferably, the adhesive layer 7 has a haze of 30% or less. Preferably, the adhesive layer 7 has a refractive index greater than 1. Preferably, the adhesive layer 7 includes at least one of an acrylic-based material, an epoxy-based material, and a urethane-based material.

The bonding sheet 4 may be at least a transparent layer having a refractive index greater than 1. Accordingly, the bonding sheet 4 does not necessarily require the base material 8, and the bonding sheet 4 may include a transparent resin layer, a transparent gel layer, or the like instead of the adhesive layer 7.

Preferably, each of the plurality of reflective layers 6 has dimensions greater than or equal to two times and less than or equal to 10 times dimensions of the LED 3. Preferably, each of the plurality of reflective layers 6 has a circular shape and a central axis of the reflective layer 6 is disposed at a position substantially corresponding to a central axis of each of the plurality of LEDs 3.

Preferably, the adhesive layer 7 has a thickness greater than a thickness of each of the plurality of LEDs 3.

Each of the plurality of LEDs 3 is an unpackaged bare chip. As a bare chip, the luminescent color is monochromatic and is typically blue. Alternatively, the LEDs 3 of an RGB tri-color type may be used with the respective colors arranged side-by-side. The element structure of each of the plurality of LEDs 3 is a flip-chip type described later, and each of the plurality of LEDs 3 is directly mounted to the substrate 2 as a bare chip as is by bumps or solder. While a bare chip is used as the LED 3 in the present embodiment, the LED is not limited thereto, and a similar effect can be obtained even when a packaged LED is used.

The substrate 2 is a general circuit substrate with glass epoxy, a polyimide, aluminum or the like as the base material. Typically, the plurality of the LEDs 3 are mounted in a matrix shape at a specific interval. An electrode pad connected to each of the plurality of LEDs 3 is further connected to a power source by a cable or the like (not illustrated) through a wiring line formed on the substrate 2. Preferably, a specific electric current can be controlled and applied to each of the plurality of LEDs 3 from the power source. The substrate reflective layer 35 is provided on the electrode pad to increase a light reflectivity. This substrate reflective layer 35 is formed using the same material and at substantially the same film thickness as those of each of the plurality of reflective layers 6 formed on the bonding sheet 4.

The LED light source substrate 1 includes a fluorescent sheet 13. The fluorescent sheet 13 absorbs the wavelength of light emitted from the plurality of LEDs 3 and emits light of the color that is a complementary color, turning the color of the emission light to white. If the light emitted from the plurality of LEDs 3 is blue, the fluorescent sheet 13 is obtained by dispersing a fluorescent material that emits yellow or green and red light into a resin or the like. As a specific product of the fluorescent sheet 13, there is quantum dot enhancement film (QDEF) manufactured by 3M (trade name) or the like. The fluorescent sheet 13 is not needed as long as another whitening method is provided such as when three types of LEDs 3 respectively emitting the three primary colors, red (R), green (G), and blue (B) are disposed on the substrate 2. When a packaged LED is used, white light emission can be achieved by adding phosphor to the sealing resin of the package.

The LED light source substrate 1 further includes an optical sheet 14. The optical sheet 14 is an optical member for changing the light emitted from a point (the LED 3) into a uniform surface light source, and a diffuser plate, a diffuser sheet, a prism sheet, a polarizing reflection sheet, and the like are used as necessary.

As the diffuser plate, a Sumipex (trade name) Opal plate manufactured by Sumitomo Chemical or the like is used in the optical sheet 14 to resolve unevenness. As a diffuser sheet, D114 manufactured by Tsujiden Co., Ltd., or the like is used in the optical sheet 14 to resolve unevenness. As a prism sheet, a brightness enhancement film (BEF) manufactured by 3M (trade name) or the like is used in the optical sheet 14 to enhance brightness. As a polarizing reflection sheet, a dual brightness enhancement film (DBEF) manufactured by 3M (trade name) or the like is used in the optical sheet 14 to enhance brightness.

Further, when a dielectric mirror sheet designed to transmit light of a color emitted from the LED 3 and reflect light of a complementary color is provided, brightness may increase.

The optical sheet 14 is typically layered in the order of the LED, the dielectric mirror sheet, the fluorescence emission sheet, the diffuser sheet, the prism sheet, the prism sheet, and the polarizing reflection sheet.

The bonding sheet 4 is obtained by forming the adhesive layer 7 that is light-transmitting on the base material 8 that is light-transmitting, such as polyethylene terephthalate (PET), and is bonded to the LED mounting surface of the substrate 2, thereby extruding air bubbles while deforming the soft adhesive layer 7. The higher the refractive index of the adhesive layer 7, the greater the effect of increasing the luminous efficiency of the LEDs 3.

The LED light source substrate 1 further includes a frame 12. The frame 12 is a frame for holding an optical member, and is formed by molding with a resin or the like having a high reflectivity. A representative example of a resin having a high reflectivity is a white polycarbonate.

FIG. 2A is a cross-sectional view illustrating a mounted state of the LED 3 of a flip-chip type provided to the LED light source substrate 1, FIG. 2B is a cross-sectional view illustrating a mounted state of an LED 93 of a face-up type, FIG. 2C is a cross-sectional view illustrating a configuration of the LED 3 of the flip-chip type, and FIG. 2D is a cross-sectional view illustrating a configuration of the LED 93 of the face-up type. Constituent elements similar to the constituent elements described above are given the same reference numerals, and detailed descriptions thereof are not repeated.

There are two types of LEDs: a face-up type and flip-chip type. The LED 93 of the face-up type, as illustrated in FIGS. 2(b) and (d), is provided with an electrode surface on an upper face, and thus wire bonding 92 is used for electrical connection to the substrate 2. The LED 3 of the flip-chip type, as illustrated in FIGS. 2(a) and (c), is provided with an electrode surface on a lower face, and thus can be directly mounted to the substrate 2 using gold bumps 15 and solder.

In the present embodiment, the bonding sheet 4 provided with the adhesive layer 7 is bonded from above the LED 3 to the substrate 2 and thus, in the case of the face-up type, the wire bonding 92 may interfere with the bonding, causing air bubbles to enter the adhesive layer 7, or the wire bonding 92 may break or come into contact with another location, causing failure. Accordingly, in the present embodiment, the LED 3 of the flip-chip type is used.

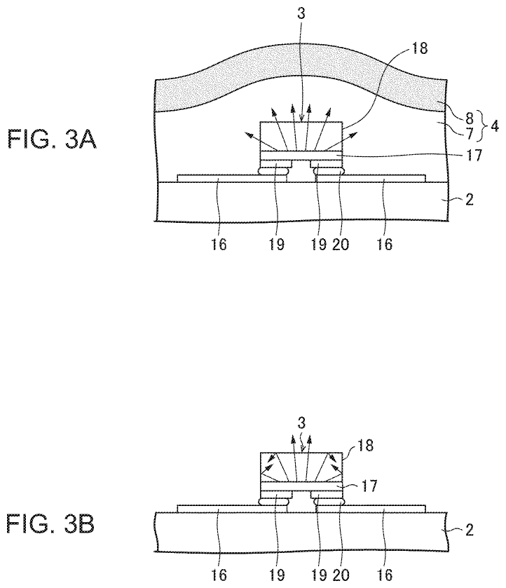

FIG. 3A is an enlarged cross-sectional view of the LED 3 of the LED light source substrate 1, and FIG. 3B is an enlarged cross-sectional view of the LED 3 of an LED light source substrate according to the comparative example. Constituent elements similar to the constituent elements described above are given the same reference numerals, and detailed descriptions thereof are not repeated.

When the periphery of the LED 3 is an air layer, it is known that light emitted at a wide angle from a light-emitting layer 17 of the LED 3 is totally reflected at an inner surface of a sapphire substrate 18, as illustrated in FIG. 3B, making it difficult to emit the light from inside the LED 3, and thus decreasing the luminous efficiency of the LED 3.

On the other hand, when the refractive index of the periphery of the LED 3 is high, the light emitted at a wide angle from the light-emitting layer 17 of the LED 3 is no longer totally reflected on the inner surface of the sapphire substrate 18, and thus the luminous efficiency of the LED 3 is improved. When the periphery of the LED 3 is a material having a refractive index (n>1.75) particularly larger than that of the sapphire substrate 18, all light emitted from the light-emitting layer 17 is emitted from the sapphire substrate 18 without being totally reflected at the inner surface of the sapphire substrate 18, and thus setting the refractive index to n>1.75 or greater is meaningless (strictly speaking, while such a setting is not meaningless since a GaN layer or the like having a further higher refractive index is present, the layer is quite thin and thus there is less effect). Even when the refractive index is n<1.75, the higher the refractive index, the greater the improvement in luminous efficiency. Therefore, the adhesive layer 7 can be considered effective as long as the adhesive layer 7 has a refractive index greater than at least that of air.

The LED 3 becomes high in temperature when turned on, and thus preferably the adhesive layer 7 is an adhesive layer having little discoloration and the like even at high temperatures. Further, preferably the adhesive layer 7 has high transparency from the perspective of increasing brightness.

The material of the adhesive layer 7 most suitable to the above conditions is a silicon-based adhesive (refractive index n=approximately 1.41). A silicon-based adhesive has excellent heat resistance and little discoloration. A silicon-based adhesive has a slightly low refractive index.

An acrylic-based adhesive (refractive index n=1.49) also has an extremely high transparency, although the heat resistance is not to the extent of that of the silicon-based adhesive, and therefore can be applied as the material of the adhesive layer 7.

Note that using these materials as a base and dispersing metal oxide nanoparticles, such as TiO₂ and ZrO₂, in the adhesive layer 7 or introducing sulfur having a high atomic refraction to increase the refractive index of the adhesive layer 7 makes it possible to significantly improve the luminous efficiency of the LED 3 and is thus particularly preferred.

Further, note that, naturally, the LED 3 is very small and has a very small area (for example, 0.1 mm×0.2 mm or the like) for a connecting portion, such as a solder 20, with the substrate 2, and thus, peeling from the substrate 2 may occur with some kind of impact. According to the present embodiment, however, the base material 8 of the bonding sheet 4 also serves to protect the LED 3, resulting in the additional effect that the LED 3 is not likely to fail.

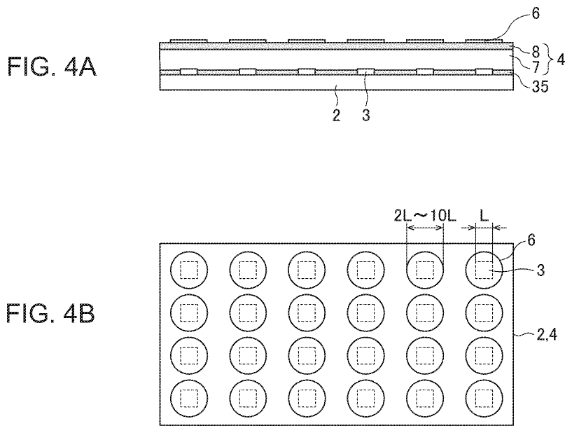

FIG. 4A is a cross-sectional view according to the substrate 2, the bonding sheet 4, and the plurality of reflective layers 6 of the LED light source substrate 1, and FIG. 4B is a top view thereof. Constituent elements similar to the constituent elements described above are given the same reference numerals, and detailed descriptions thereof are not repeated.

The bonding sheet 4 is bonded to the substrate 2 from above. The plurality of reflective layers 6 are provided on the surface of the bonding sheet 4, at or near areas directly above the LEDs 3. Each of the plurality of reflective layers 6 is preferably constituted by a white ink layer. According to this configuration, light having a strong intensity emitted from the plurality of LEDs 3 directly upward can be respectively reflected by the plurality of reflective layers 6 and mitigated, and thus the unevenness in brightness is improved.

Preferably, each of the plurality of reflective layers 6 has a dimension somewhat larger than an outer diameter dimension of each of the plurality of LEDs 3, making it possible to reflect the light emitted from side surfaces of the plurality of LEDs 3 as well. For example, as illustrated in FIG. 4B, given L as the dimension of one side of the LED 3, the dimension of the reflective layer 6 is preferably greater than or equal to 2 L and less than or equal to 10 L.

A shape of each of the plurality of reflective layers 6 is typically circular, and a central axis of each of the plurality of LEDs 3 and a respective central axis of the circular shape of each of the plurality of reflective layers 6 substantially coincide, as illustrated in FIG. 4B. With such a configuration, light emitted in all directions from the plurality of LEDs 3 can be efficiently shielded.

As the method for forming the plurality of reflective layers 6, a method of printing white ink on the bonding sheet 4 using an inkjet printing machine is most efficient. Other printing methods such as screen printing may also be used. As another method of forming the plurality of reflective layers 6, a metal thin film may be formed by a method such as vapor deposition.

A plurality of the reflective layers 6 are provided in a matrix in correspondence with the plurality of the LEDs 3 arranged in a matrix on the substrate 2.

Note that, metal wiring lines are provided on the surface of the substrate 2, and the substrate reflective layer 35 is formed thereon using the same material as that of the reflective layer 6. Accordingly, in a case where the material of the reflective layer 6 has electrical conductivity, a leak occurs between the metal wiring lines, causing failure of the substrate 2, and thus the reflective layer 6 needs to have electrical insulating properties. That is, a highly reflective metal material such as aluminum or silver cannot be used in the reflective layer 6, and the material that can be used in the reflective layer 6 is limited to an insulating material such as an ink material. However, when an insulating layer is separately provided on the metal wiring line of the substrate 2, materials are not limited to above, the reflective layer 6 does not need to have insulating properties.

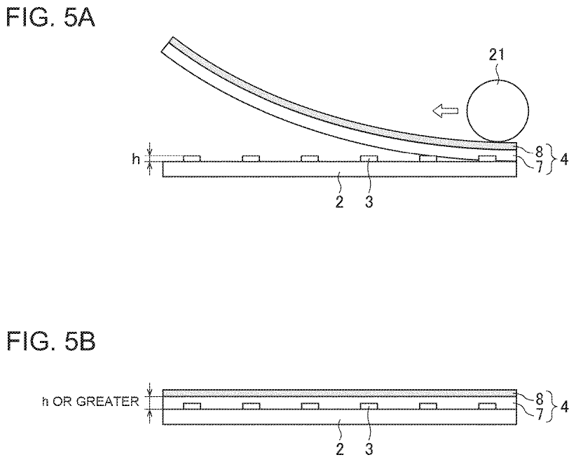

FIG. 5A is a cross-sectional view illustrating a method for forming the bonding sheet 4, and FIG. 5B is a cross-sectional view illustrating the bonding sheet 4 formed on the substrate 2. Constituent elements similar to the constituent elements described above are given the same reference numerals, and detailed descriptions thereof are not repeated.

As illustrated in FIG. 5A, the bonding sheet 4, which is obtained by forming the adhesive layer 7 that is light-transmitting on the base material 8 that is light-transmitting such as PET, is bonded to the substrate 2 on which the LEDs 3 are mounted, using a roller 21 or the like. This makes it possible to readily extrude the air surrounding the plurality of LEDs 3 and embed with the adhesive layer 7. Even when some air bubbles remain in the periphery of the plurality of LEDs 3, the air bubbles can be eliminated by autoclaving. The autoclaving conditions are, for example, 45° C., 0.5 MPa, 20 minutes, and the like.

The base material 8 is preferably a material having high transparency. Examples of the material include PET, acrylic, polycarbonate, and the like. The material of the adhesive layer 7 is preferably a material having favorable transparency and high adhesive strength to the surface of the substrate 2. For example, adhesive materials such as acrylic-based, epoxy-based, and urethane-based adhesive materials are preferred. The adhesive strength of the adhesive layer 7 is preferably 10 N/cm or higher, for example.

The adhesive layer 7, which is thick to a certain degree, is required to adhere the periphery of the plurality of LEDs 3 without an air interface. Given h as the height of each of the plurality of LEDs 3, when the thickness of the first adhesive layer 7 is h or less, air bubbles often remain and the space is not embedded even when autoclaving is performed. Accordingly, the thickness of the adhesive layer 7 is preferably greater than h. Further, as an alternative to the bonding sheet 4, a transparent layer may be formed by spraying a transparent resin onto the substrate 2, on which the plurality of LEDs 3 are mounted, using a spray or the like.

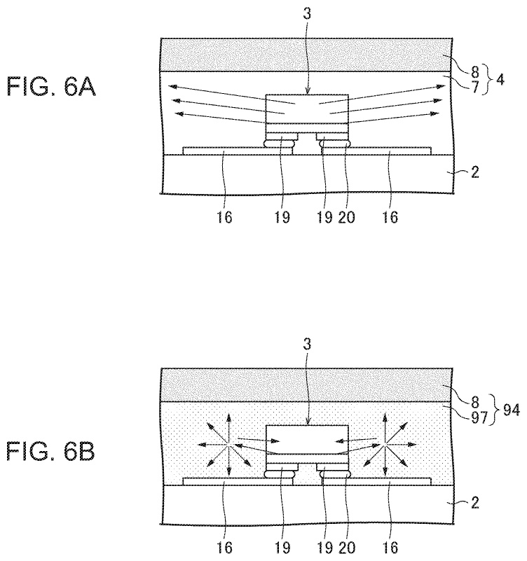

FIG. 6A is a cross-sectional view for describing an effect of the adhesive layer 7 provided to the bonding sheet 4, and FIG. 6B is a cross-sectional view illustrating an adhesive layer 97 according to a comparative example. Constituent elements similar to the constituent elements described above are given the same reference numerals, and detailed descriptions thereof are not repeated.

The adhesive layer 7 is preferably transparent to the extent possible, and does not include light diffusing particles or the like. In the case of the adhesive layer 97 in which light diffusing particles made from titanium oxide or the like are mixed, depending on the concentration of the light diffusing particles, the light emitted from the LED 3 is scattered at or near the LED 3 and re-enters the LED 3 itself, or the light emitted from the LED 3 comes across and is absorbed by an electrode pad 16, the solder 20, and the like having a low reflectivity on the substrate 2. Preferably, the adhesive layer 7 is transparent to the extent possible and the light once emitted from the LED 3 travels far away. Specifically, the adhesive layer 7 has preferably a haze of 30% or less.

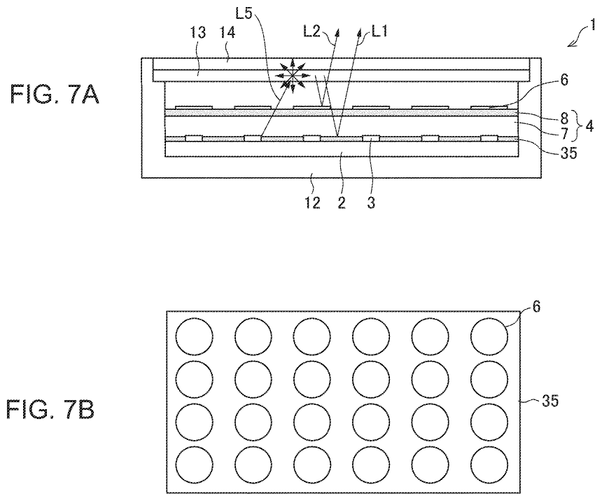

FIG. 7A and FIG. 7B are cross-sectional views for describing an effect of the substrate reflective layer 35 provided to the LED light source substrate 1. Constituent elements similar to the constituent elements described above are given the same reference numerals, and detailed descriptions thereof are not repeated.

In the present embodiment, the reflective layer 6 and the substrate reflective layer 35 are formed of the same material and to substantially the same film thickness. That is, in the present embodiment, the reflectivity and the tinge of the reflective layer 6 and the substrate reflective layer 35 are substantially the same. Thus, when the LED light source substrate 1 is viewed from a top surface side opposite to the substrate 2 relative to the reflective layer 6, the plurality of LEDs 3 are hidden by the plurality of reflective layers 6 and the LED light source substrate 1 appears to not include the plurality of LEDs 3. This state was found to be very effective in reducing the unevenness of the backlight.

The fluorescent sheet 13 absorbs light L5 emitted from the plurality of LEDs 3 and emits a color that is a complementary color to the absorbed light L5. As illustrated in FIG. 7A, the fluorescent sheet 13 uniformly emits a color that is a complementary color of the absorbed light L5 in substantially all directions. That is, ½ of the light emitted by the fluorescent sheet 13 is emitted toward the substrate 2.

When the reflectivities and the tinges of, among the light emitted by the fluorescent sheet 13 toward the substrate 2, the light L2 reflected by the plurality of reflective layers 6 and the light L1 reflected by the substrate reflective layer 35 differ, the unevenness of the backlight was found to be easily recognized. In particular, unevenness is easily visible when the tinges differ. The tinge of the plurality of reflective layers 6 is a property specific to the material, and thus it is easiest and highly effective to form the plurality of reflective layers 6 and the substrate reflective layer 35 from the same material.

Further, even when it is necessary to unavoidably form the plurality of reflective layers 6 and the substrate reflective layer 35 from different materials, when the tinge of the plurality of reflective layers 6 and the tinge of the substrate reflective layer 35 are closely matched by fine adjustment or the like of pigments included in the plurality of reflective layers 6, the effect of reducing the unevenness of the backlight is similarly obtained. The reflectivity depends on the material and the thickness of the plurality of reflective layers 6 and the substrate reflective layer 35. As long as the material is the same and the thickness is substantially equal, the plurality of reflective layers 6 and the substrate reflective layer 35 have similar reflectivity.

However, strictly speaking, the substrate reflective layer 35 covered by the adhesive layer 7 has a lower reflectivity than that of the plurality of reflective layers 6 even when the thickness is the same as that of the plurality of reflective layers 6. Accordingly, it may be better that the substrate reflective layer 35 has a film thickness that is thicker to some extent than that of the plurality of reflective layers 6. Thus, preferably, a ratio of the thickness of the substrate reflective layer 35 to the thickness of each of the plurality of reflective layers 6 is greater than or equal to 1 and less than or equal to 1.5.

The prism sheet, the diffuser sheet, and the polarizing reflection sheet included in the optical sheet 14 are also sheets that have an effect of increasing brightness and increasing uniformity while returning light from the plurality of LEDs 3 toward the substrate 2. Accordingly, similar to the fluorescent sheet 13, the reflectivity and tinge of the plurality of reflective layers 6 affect the unevenness. By making the reflectivity of the substrate reflective layer 35 substantially equal to the reflectivity of the plurality of reflective layers 6, the unevenness of the backlight produced by the optical sheet 14 can be reduced in the same manner as with the fluorescent sheet 13.

### Second Embodiment

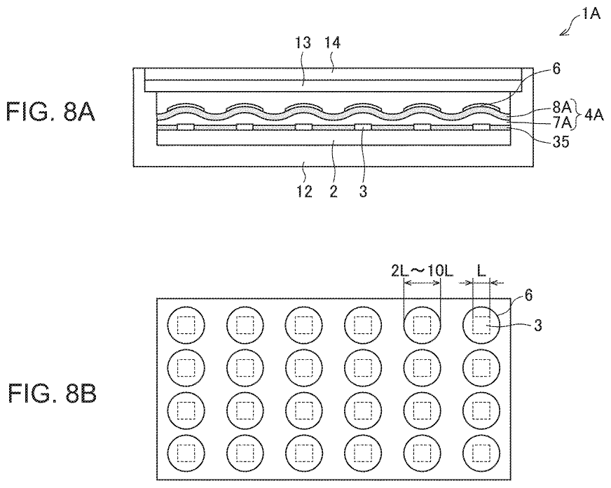

FIG. 8A is a cross-sectional view of an LED light source substrate 1A according to the second embodiment, and FIG. 8B is a plan view thereof. Constituent elements similar to the constituent elements described above are given the same reference numerals, and detailed descriptions thereof are not repeated.

The LED light source substrate 1A includes a bonding sheet 4A. The bonding sheet 4A includes an adhesive layer 7A and a base material 8A. Given h as the height of the LED 3, a thickness of the adhesive layer 7A is greater than or equal to h and less than 2 h. Then, the thickness of the base material 8A is greater than or equal to 25 μm and less than 200 μm.

TABLE 1

| | | Thickness of adhesive layer 7A | | |
|---|---|---|---|---|
| | | h or less | From h to 2 h | 2 h or greater |
| Thickness | 12 μm | Poor: Air | Fair: Wrinkles | Fair: Some |
| of base | or | bubbles | formed at | improvement in |
| material | less | remain | forming adhesive | light extraction |
| 8A | | around bare | layer | efficiency |
| | | chip | | |
| | From 12 | Poor: Air | Good: High light | Fair: Some |
| | to | bubbles | extraction | improvement in |
| | 200 μm | remain | efficiency | light extraction |
| | | around bare | | efficiency |
| | | chip | | |
| | 200 μm | Poor: Air | Fair: Some | Fair: Some |
| | or | bubbles | improvement in | improvement in |
| | greater | remain | light extraction | light extraction |
| | | around bare | efficiency | efficiency |
| | | chip | | |

When thus configured, as shown in the Table 1 above and illustrated in FIG. 8A, it is understood that the base material 8A deforms following the plurality of LEDs 3, becoming convex in correspondence with each of the plurality of LEDs 3, and the light extraction efficiency of the plurality of LEDs 3 is significantly enhanced.

When the thickness of the adhesive layer 7A is greater than or equal to 2 h, the base material 8A remains substantially flat regardless of the presence or absence of the plurality of LEDs 3, and thus the effect of improving the light extraction efficiency is limited. Further, when a thickness of the base material 8A is greater than or equal to 200 μm as well, the base material 8A does not deform following the plurality of LEDs 3 and is flat, and thus the effect of improving the light extraction efficiency is limited.

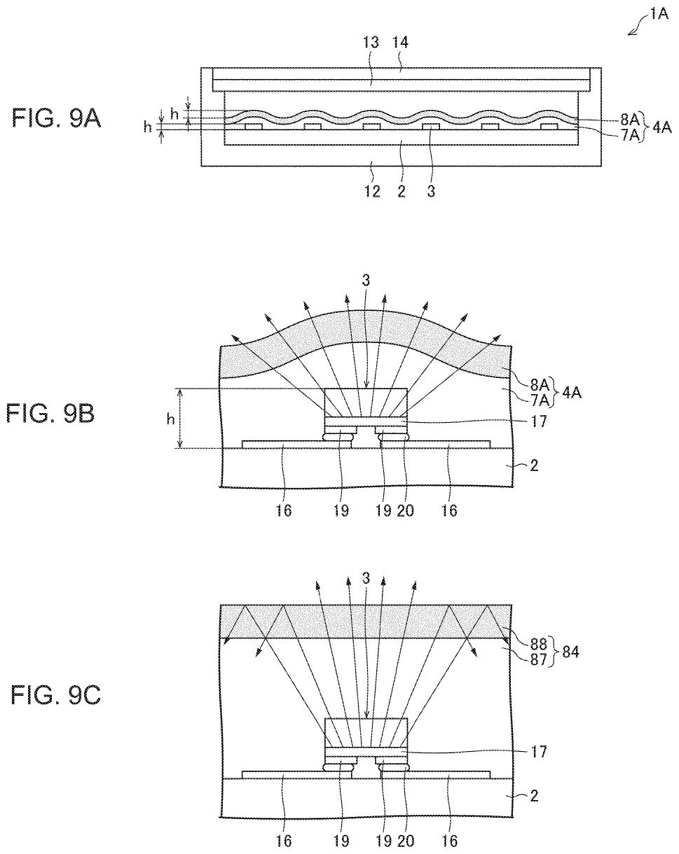

FIG. 9A is a cross-sectional view describing an effect of the LED light source substrate 1A according to the second embodiment, FIG. 9B is a cross-sectional view illustrating the base material 8A of the bonding sheet 4A provided to the LED light source substrate 1A, and FIG. 9C is a cross-sectional view illustrating a base material 88 of a bonding sheet 84 according to a comparative example. Constituent elements similar to the constituent elements described above are given the same reference numerals, and detailed descriptions thereof are not repeated.

When a surface shape of the base material 8A is convex about the LED 3, an angle of light incident on an interface between the base material 8A and the air from the LED 3 changes, causing the light emitted from the LED 3 to emit more readily and the luminous efficiency of the LED 3 to improve. A height of the convex and recesses of the surface shape of the base material 8A is substantially about the height h of the LED 3.

When the adhesive layer 7A is made thicker or the base material 8A is made thicker, and the surface shape of the base material 8A is not convex about the LED 3, the surface shape of the base material 88 is flat as illustrated in FIG. 9C, and the improvement in efficiency of the LED 3 is limited.

### Third Embodiment

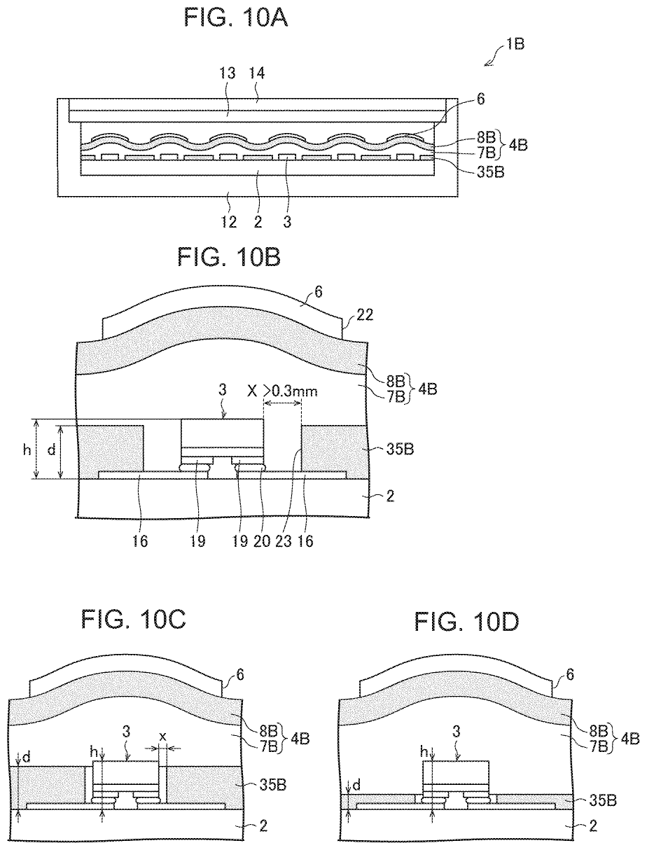

FIG. 10A is a cross-sectional view of an LED light source substrate 1B according to the third embodiment, FIG. 10B is a cross-sectional view illustrating a relationship between a substrate reflective layer 35B and the LED 3 provided to the LED light source substrate 1B, FIG. 10C is a cross-sectional view illustrating a relationship between a substrate reflective layer 95 and the LED 3 according to a comparative example, and FIG. 10D is a cross-sectional view illustrating a relationship between the substrate reflective layer 35 and the LED 3 according to a modified example. Constituent elements similar to the constituent elements described above are given the same reference numerals, and detailed descriptions thereof are not repeated.

The substrate reflective layer 35B is formed including an end face 23 thereof extending to a position closer to the LED 3 than a position corresponding to an end face 22 of the reflective layer 6. And, a gap between the end face 23 of the substrate reflective layer 35B and the LED 3 is greater than 0.3 mm.

The reflective layer 6 increases in reflectivity depending on the thickness. Accordingly, in order to make the backlight provided with the LED light source substrate 1B thinner, it is necessary to increase the reflectivity of the reflective layer 6 to more effectively shield light, having a strong intensity, emitted directly upward from the LED 3.

When a thickness d of the substrate reflective layer 35B is large (when the thickness d is substantially close to the height h of the LED 3, such as 0.3 mm, for example) and a distance X between the substrate reflective layer 35B and the LED 3 is short, as illustrated in FIG. 10C, the adhesive layer 7B may not enter the gap between the substrate reflective layer 35B and the LED 3 and air bubbles that have entered into the gap between the substrate reflective layer 35B and the LED 3 may not disappear even when autoclaving or the like is performed. This means that an emitting surface of the LED 3 comes into contact with the air layer, which leads to a decrease in light emission efficiency. When the distance X is 0.3 mm or less, air bubbles, although also dependent on the thickness d of the LED 3 and the substrate reflective layer 35B, were found to significantly occur. Accordingly, preferably X>0.3 mm. Further, when the distance X is too long and the end face 23 of the substrate reflective layer 35B is separated from the LED 3 to a greater degree than a position corresponding to the end face 22 of the reflective layer 6 formed on the base material 8B, the electrode pad 16 is exposed when viewed from the base material 8B side of the substrate 2, causing an occurrence of unevenness of the backlight, which is not preferred.

When the thickness d of the substrate reflective layer 35B is sufficiently thin compared to the height h of LED 3, as illustrated in FIG. 10D, the emitting surface of the LED 3 does not come into contact with the air layer and is embedded in the adhesive layer 7B, and thus there is no decrease in light emission efficiency.

### Fourth Embodiment

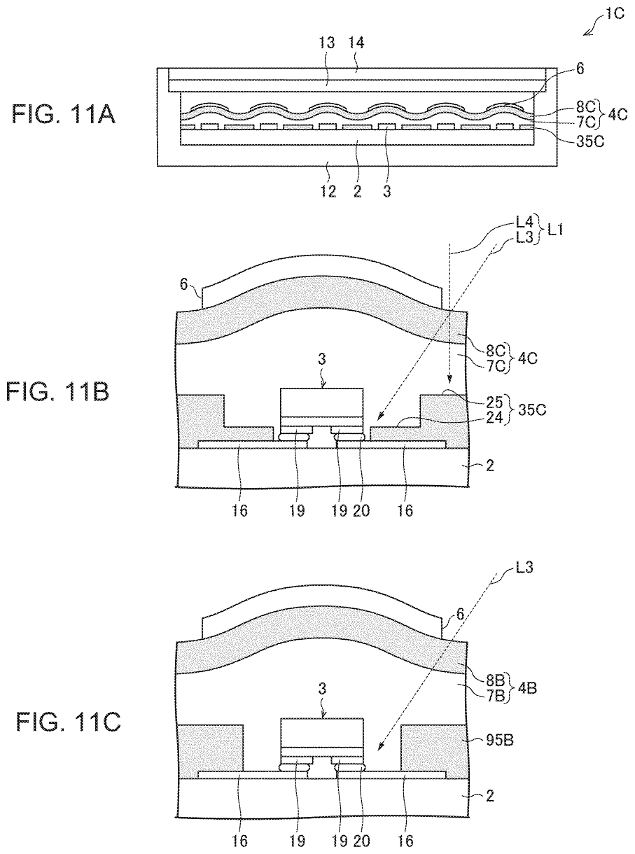

FIG. 11A is a cross-sectional view of an LED light source substrate 1C according to embodiment 4, FIG. 11B is a cross-sectional view illustrating a relationship between a substrate reflective layer 35C and the LED 3 provided to the LED light source substrate 1C, and FIG. 11C is a cross-sectional view illustrating a relationship between a substrate reflective layer 95B and the LED 3 according to a comparative example. Constituent elements similar to the constituent elements described above are given the same reference numerals, and detailed descriptions thereof are not repeated.

The first light L1 that passes between the plurality of reflective layers 6 and is incident on the bonding sheet 4C includes obliquely incident light L3 that passes between the plurality of reflective layers 6 obliquely with respect to the substrate 2 and is incident on a bonding sheet 4C, and incident light L4 that passes substantially orthogonally to the substrate 2 between the plurality of reflective layers 6 and is incident on the bonding sheet 4C.

The substrate reflective layer 35C includes an oblique light reflective portion 24, formed around the LED 3, configured to reflect the obliquely incident light L3, and an incident light reflective portion 25 configured to reflect the incident light L4. The oblique light reflective portion 24 is formed thinner than the incident light reflective portion 25.

Thus, providing the oblique light reflective portion 24 having a thin thickness to the substrate reflective layer 35C at or near the LED 3 is even more effective. This is because, as illustrated in FIG. 11C, when the oblique light reflective portion 24 is not provided, the electrode pad 16, the LED 3, and the like are obliquely visible. When the oblique light reflective portion 24 is provided, the reflectivity for the obliquely incident light L3 when the substrate 2 is obliquely viewed can be made substantially constant, making it possible to effectively reduce the unevenness of the backlight in an oblique field of view.

The substrate reflective layer 35C including the oblique light reflective portion 24 and the incident light reflective portion 25 having different thicknesses can be formed without particular problems by firstly forming a thin reflective layer with a pattern including edges at or near the periphery of the LED 3, and then forming a thick reflective layer with a pattern including edges separated from the LED 3.

Supplement

A light emitting diode (LED) light source substrate 1, 1A, 1B, and 1C according to a first aspect of the disclosure includes a substrate 2, a plurality of LEDs 3 of a flip-chip type mounted on the substrate 2, a transparent layer (bonding sheet 4, 4A, 4B, and 4C) formed on the substrate 2, embedding the plurality of LEDs 3, and having a refractive index greater than 1, a plurality of reflective layers 6 formed on the transparent layer (bonding sheet 4, 4A, 4B, and 4C) in correspondence with the plurality of LEDs 3, and a substrate reflective layer 35, 35B, and 35C, formed on the substrate 2, configured to reflect a first light L1 that passes between the plurality of reflective layers 6 and is incident on the transparent layer (bonding sheet 4, 4A, 4B, and 4C). A reflectivity of the substrate reflective layer 35, 35B, and 35C configured to reflect the first light L1 is substantially equal to a reflectivity of the plurality of reflective layers 6 configured to reflect a second light L2 incident on the plurality of reflective layers 6 from a side opposite to the substrate 2.

According to the configuration described above, the first light that passes between the plurality of reflective layers and is incident on the transparent layer and the second light incident on the plurality of reflective layers from the side opposite to the substrate are reflected at the same reflectivity. Therefore, a distribution of reflectivity does not occur between the first light reflected by the substrate reflective layer and the second light reflected by each of the plurality of reflective layers. As a result, an unevenness of the output light from the backlight provided with the LED light source substrate can be suppressed.

In the LED light source substrate 1, 1A, 1B, and 1C according to a second aspect of the disclosure, in the first aspect described above, preferably each of the plurality of LEDs 3 is a bare chip.

According to the configuration described above, an unevenness of the output light from the backlight provided with the LED light source substrate including bare chip type LEDs can be suppressed.

In the LED light source substrate 1, 1A, 1B, and 1C according to a third aspect of the disclosure, in the first aspect described above, preferably the substrate reflective layer 35, 35B, and 35C is formed of a same material as that of the plurality of reflective layers 6.

According to the configuration described above, the reflectivity of the substrate reflective layer and the reflectivity of the reflective layers are substantially the same.

In the LED light source substrate 1, 1A, 1B, and 1C according to a fourth aspect of the disclosure, in the third aspect described above, preferably a ratio of a thickness of the substrate reflective layer 35, 35B, and 35C to a thickness of each of the plurality of reflective layers 6 is greater than or equal to 1 and less than or equal to 1.5.

According to the configuration described above, the reflectivity of the substrate reflective layer and the reflectivity of the plurality of reflective layers can be made nearly the same.

In the LED light source substrate 1B according to a fifth aspect of the disclosure, in the first aspect described above, preferably the substrate reflective layer 35B is formed including an end face 23 of the substrate reflective layer 35B extending to a position closer to the plurality of LEDs 3 than a position corresponding to an end face 22 of each of the plurality of reflective layers 6, and a gap (distance X) between the end face 23 of the substrate reflective layer 35B and each of the plurality of LEDs 3 is greater than 0.3 mm.

According to the configuration described above, the occurrence of air bubbles in the gap between the end face of the substrate reflective layer and each of the plurality of LEDs can be suppressed.

In the LED light source substrate 1C according to a sixth aspect of the disclosure, in the first aspect described above, preferably the first light L1 includes obliquely incident light L3 that passes between the plurality of reflective layers 6 obliquely to the substrate 2 and is incident on the transparent layer (bonding sheet 4C), and the substrate reflective layer 35C includes an oblique light reflective portion 24, formed around the plurality of LEDs 3, configured to reflect the obliquely incident light.

According to the configuration described above, an unevenness of an oblique field of view of the output light from the backlight provided with the LED light source substrate can be effectively reduced.

In the LED light source substrate 1C according to a seventh aspect of the disclosure, in the sixth aspect described above, preferably the first light L1 further includes incident light L4 that passes between the plurality of reflective layers 6 substantially orthogonally to the substrate 2 and is incident on the transparent layer (bonding sheet 4C), the substrate reflective layer 35C further includes an incident light reflective portion 25 configured to reflect the incident light L4, and the oblique light reflective portion 24 is formed more thinly than the incident light reflective portion 25.

According to the configuration described above, the unevenness of the oblique field of view of the output light from the backlight can be effectively reduced.

In the LED light source substrate 1, 1A, 1B, and 1C according to an eighth aspect of the disclosure, in the first aspect described above, preferably the transparent layer (bonding sheet 4, 4A, 4B, and 4C) includes a resin layer (adhesive layer 7, 7A, 7B and, 7C) formed on the substrate 2, embedding the plurality of LEDs 3, and a base material (8, 8A, 8B, and 8C) formed on the resin layer (adhesive layer 7, 7A, 7B, and 7C).

According to the configuration described above, the bonding sheet in which the resin layer is formed on the substrate can be easily bonded to the substrate on which the LEDs are mounted using a roller or the like.

In the LED light source substrate 1, 1A, 1B, and 1C according to a ninth aspect of the disclosure, in the eighth aspect described above, preferably the resin layer includes an adhesive layer 7, 7A, 7B, and 7C.

According to the configuration described above, a luminous efficiency of the plurality of LEDs is improved by the high refractive index of the adhesive layer.

In the LED light source substrate 1, 1A, 1B, and 1C according to a tenth aspect of the disclosure, in the eighth aspect described above, preferably the resin layer (adhesive layer 7, 7A, 7B, and 7C) has a haze of 30% or less.

According to the configuration described above, light emitted from the plurality of LEDs can be suppressed from being scattered at or near the plurality of LEDs.

In the LED light source substrate 1, 1A, 1B, and 1C according to an eleventh aspect of the disclosure, in the eighth aspect described above, preferably the resin layer (adhesive layer 7, 7A, 7B, and 7C) has a refractive index greater than 1.

According to the configuration described above, the luminous efficiency of the plurality of LEDs 3 is improved by the high refractive index of the adhesive layer.

In the LED light source substrate 1, 1A, 1B, and 1C according to a twelfth aspect of the disclosure, in the eighth aspect described above, preferably the resin layer (adhesive layer 7, 7A, 7B, and 7C) includes at least one of an acrylic-based material, an epoxy-based material, and a urethane-based material.

According to the configuration described above, a transparency of the resin layer can be increased, and an adhesive strength of the resin layer to the substrate can be increased.

In the LED light source substrate 1, 1A, 1B, and 1C according to a thirteenth aspect of the disclosure, in the first aspect described above, preferably each of the plurality of reflective layers 6 has dimensions greater than or equal to two times and less than or equal to 10 times dimensions of each of the plurality of LEDs 3.

According to the configuration described above, light emitted from a side surface of each of the plurality of LEDs can also be reflected by each of the plurality of reflective layers 6.

In the LED light source substrate 1, 1A, 1B, and 1C according to a fourteenth aspect of the disclosure, in the first aspect described above, preferably each of the plurality of reflective layers 6 has a circular shape, and a central axis of each of the plurality of reflective layers 6 is disposed at a position respectively corresponding to a central axis of each of the plurality of LEDs 3.

According to the configuration described above, light emitted from each of the plurality of LEDs in all directions can be efficiently shielded by each of the plurality of reflective layers.

In the LED light source substrate 1, 1A, 1B, and 1C according to a fifteenth aspect of the disclosure, in the eighth aspect described above, preferably the resin layer (adhesive layer 7, 7A, 7B, and 7C) has a thickness greater than a thickness of each of the plurality of LEDs 3.

According to the configuration described above, the plurality of LEDs can be adhered to the resin layer without an interface between each of the plurality of LEDs and the air.

In the LED light source substrate 1, 1A, 1B, and 1C according to a sixteenth aspect of the disclosure, in the first aspect described above, preferably the transparent layer (bonding sheet 4, 4A, 4B, and 4C) has a convex shape corresponding to each mounting position of the plurality of LEDs 3.

According to the configuration described above, a light extraction efficiency of each of the plurality of LEDs can be significantly increased.

In the LED light source substrate 1, 1A, 1B, and 1C according to a seventeenth aspect of the disclosure, in the sixteenth aspect described above, preferably the convex shape has a height substantially equal to a thickness of each of the plurality of LEDs 3.

According to the configuration described above, an angle of light incident on the interface between the bonding sheet and the air from each of the plurality of LEDs changes compared to a case where the shape is not convex. Therefore, total reflection of light incident on the interface from each of the plurality of LEDs is suppressed. As a result, the light emitted from the plurality of LEDs is readily emitted through the bonding sheet, improving the luminous efficiency of the LEDs 3.

An illumination device according to an eighteenth aspect of the disclosure includes the LED light source substrate 1, 1A, 1B, and 1C according to any one of the first to seventeenth aspects described above.

The disclosure is not limited to each of the embodiments described above, and various modifications may be made within the scope of the claims. Embodiments obtained by appropriately combining technical approaches disclosed in each of the different embodiments also fall within the technical scope of the disclosure. Moreover, novel technical features can be formed by combining the technical approaches disclosed in the embodiments.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A light emitting diode (LED) light source substrate comprising:
a substrate;
a plurality of LEDs of a flip-chip type mounted on the substrate;
a transparent layer formed on the substrate, embedding the plurality of LEDs, and having a refractive index greater than 1;
a plurality of reflective layers formed on the transparent layer in correspondence with the plurality of LEDs; and
a substrate reflective layer, formed on the substrate, configured to reflect a first light that passes between the plurality of reflective layers and is incident on the transparent layer,
wherein a reflectivity of the substrate reflective layer configured to reflect the first light is substantially equal to a reflectivity of the plurality of reflective layers configured to reflect a second light incident on the plurality of reflective layers from a side opposite to the substrate.

2. The LED light source substrate according to claim 1,
wherein each of the plurality of LEDs is a bare chip.

3. The LED light source substrate according to claim 1,
wherein the substrate reflective layer is formed of a same material as that of the plurality of reflective layers.

4. The LED light source substrate according to claim 3,
wherein a ratio of a thickness of the substrate reflective layer to a thickness of each of the plurality of reflective layers is greater than or equal to 1 and less than or equal to 1.5.

5. The LED light source substrate according to claim 1,
wherein the substrate reflective layer is formed including an end face of the substrate reflective layer extending to a position closer to the plurality of LEDs than a position corresponding to an end face of each of the plurality of reflective layers, and
a gap between the end face of the substrate reflective layer and each of the plurality of LEDs is greater than 0.3 mm.

6. The LED light source substrate according to claim 1,
wherein the first light includes obliquely incident light that passes between the plurality of reflective layers obliquely to the substrate and is incident on the transparent layer, and
the substrate reflective layer includes an oblique light reflective portion, formed around the plurality of LEDs, configured to reflect the obliquely incident light.

7. The LED light source substrate according to claim 6,
wherein the first light further includes incident light that passes between the plurality of reflective layers substantially orthogonally to the substrate and is incident on the transparent layer,
the substrate reflective layer further includes an incident light reflective portion configured to reflect the incident light, and
the oblique light reflective portion is formed more thinly than the incident light reflective portion.

8. The LED light source substrate according to claim 1,
wherein the transparent layer includes a resin layer formed on the substrate, embedding the plurality of LEDs, and a base material formed on the resin layer.

9. The LED light source substrate according to claim 8,
wherein the resin layer includes an adhesive layer.

10. The LED light source substrate according to claim 8,
wherein the resin layer has a haze of 30% or less.

11. The LED light source substrate according to claim 8,
wherein the resin layer has a refractive index greater than 1.

12. The LED light source substrate according to claim 8,
wherein the resin layer includes at least one of an acrylic-based material, an epoxy-based material, and a urethane-based material.

13. The LED light source substrate according to claim 1,
wherein each of the plurality of reflective layers has dimensions greater than or equal to two times and less than or equal to 10 times dimensions of each of the plurality of LEDs.

14. The LED light source substrate according to claim 1,
wherein each of the plurality of reflective layers has a circular shape, and
a central axis of each of the plurality of reflective layers is disposed at a position respectively corresponding to a central axis of each of the plurality of LEDs.

15. The LED light source substrate according to claim 8,
wherein the resin layer has a thickness greater than a thickness of each of the plurality of LEDs.

16. The LED light source substrate according to claim 1,
wherein the transparent layer has a convex shape corresponding to each mounting position of the plurality of LEDs.

17. The LED light source substrate according to claim 16,
wherein the convex shape has a height substantially equal to a thickness of each of the plurality of the LEDs.

18. An illumination device comprising:
the LED light source substrate described in claim 1.
